(19) United States
(12) Patent Application Publication
(10) Pub. No.: US 2025/0191531 A1
(43) Pub. Date: Jun. 12, 2025

(54) DECODER CIRCUIT AND DISPLAY DEVICE

(71) Applicants: Yunnan Invensight Optoelectronics Technology Co., Ltd., Kunming, Yunnan (CN); BOE Technology Group Co., Ltd., Beijing (CN)

(72) Inventors: Shanghong JIANG, Beijing (CN); Qingshan SHAN, Beijing (CN); Longfei FAN, Beijing (CN); Dachao LI, Beijing (CN); Pengcheng LU, Beijing (CN); Yaoxi MA, Beijing (CN)

(21) Appl. No.: 18/832,951

(22) PCT Filed: Sep. 26, 2023
(86) PCT No.: PCT/CN2023/121520

§ 371 Date: Feb. 28, 2025

(30) Foreign Application Priority Data
Nov. 21, 2022 (CN) 202211454573.2

(51) Int. Cl. G09G 3/3225; H10D 86/40

(52) U.S. Cl. CPC G09G 3/3225; H10D 86/471; G09G 2300/0426

(57) ABSTRACT

A decoder circuit and a display device are provided, which belong to the technical field of electronics. In each logic circuit group included in the decoder circuit, N-type transistors and P-type transistors are both arranged along a second direction, the N-type transistors and the P-type transistors are arranged along a first direction intersected with the second direction, substrate isolation regions of any transistor are disposed on two sides of the transistor in the first direction, and the substrate isolation region is provided with vias arranged along the second direction. In this way, the P-type transistor and the N-type transistor can be separated by the substrate isolation region with vias, so that a distance between the P-type transistor and the N-type transistor adjacent to each other is greater than a distance between two adjacent transistors of the same type (e.g., N-type transistors or P-type transistors).

The present application is a national stage of PCT application No. PCT/CN2023/121520, filed on Sep. 26, 2023, which claims priority to Chinese Patent Application No. 202211454573.2, entitled “DECODING CIRCUIT AND DISPLAY APPARATUS” and filed on Nov. 21, 2022, the entire contents of both of which are incorporated herein by reference.

### TECHNICAL FIELD

The present disclosure relates to the technical field of electronics, and in particular, to a decoder circuit and a display device.

### BACKGROUND

A decoder circuit (such as a 3-to-8 decoder) is one of the essential circuits in a display device, and is configured to convert binary data into decimal data to adapt to the display device.

The decoder circuit generally includes a plurality of interconnected logic gate circuits (such as NOT gates, NAND gates, and NOR gates). Each logic gate circuit includes at least one N-type metal-oxide-semiconductor (NMOS) transistor and one P-type metal-oxide-semiconductor (PMOS) transistor. That is, each logic gate circuit includes at least one complementary metal-oxide-semiconductor (CMOS) transistor.

However, due to a current arrangement manner, when one of the CMOS transistors is affected by interference, it may be fed back to another transistor. In this way, the PMOS transistor and the NMOS transistor in the CMOS transistor may be triggered and turned on one after another, resulting in a latch up effect.

### SUMMARY

A decoder circuit and a display device are provided. The technical solutions are as follows.

In one aspect, a decoder circuit is provided, including:
a plurality of logic circuit groups arranged sequentially along a first direction and interconnected;
each of the logic circuit groups including: a plurality of logic circuits arranged sequentially along a second direction and interconnected, the second direction being intersected with the first direction;
each of the logic circuits including: at least one N-type transistor and at least one P-type transistor interconnected, the N-type transistor and the P-type transistor each having a channel region and substrate isolation regions, the substrate isolation regions being disposed on two sides of the channel region in the first direction, and the substrate isolation regions being provided with a plurality of vias arranged sequentially along the second direction for interconnection between parts to be connected;
wherein in each of the logic circuit groups, the N-type transistors in the plurality of logic circuits are arranged sequentially along the second direction, the P-type transistors are arranged sequentially along the second direction, the P-type transistors and the N-type transistors are arranged sequentially along the first direction, and a distance between a channel region of a P-type transistor and a channel region of a N-type transistor adjacent to the P-type transistor in the first direction is greater than a distance between channel regions of two adjacent transistors of the same type, the transistors of the same type including P-type transistors and N-type transistors.

In some embodiments, each two adjacent logic circuit groups are arranged in mirror symmetry along an axis extending in the second direction.

In some embodiments, in each two adjacent logic circuit groups, transistors disposed on two sides of the axis share the same substrate isolation region.

In some embodiments, in two adjacent substrate isolation regions in the P-type transistor and the N-type transistor that are adjacent in the first direction, a distance between an edge of one substrate isolation region away from the other substrate isolation region and an edge of the other substrate isolation region away from the one substrate isolation region is greater than the distance between the channel regions of two adjacent transistors of the same type in the second direction.

In some embodiments, for each transistor in the P-type transistor and the N-type transistor that are adjacent in the first direction, in the substrate isolation regions in the transistor, a distance between the substrate isolation region close to the other adjacent transistor and the channel region of the transistor is greater than a distance between the substrate isolation region away from the other adjacent transistor and the channel region of the transistor.

In some embodiments, the distance between the channel regions of the P-type transistor and the N-type transistor that are adjacent in the first direction is greater than a difference between a width of the channel region of the P-type transistor and a width of the channel region of the N-type transistor, the width of the channel region of the P-type transistor is greater than the width of the channel region of the N-type transistor, and a direction of both the widths is parallel to the first direction.

In some embodiments, an area of the substrate isolation region of the P-type transistor is greater than an area of the substrate isolation region of the N-type transistor.

In some embodiments, in each of the logic circuits, the substrate isolation regions of the P-type transistors disposed on the same side are connected and flush in the second direction, and the channel regions of the P-type transistors are spaced apart from each other and at least one side is flush in the second direction;
and the substrate isolation regions of the N-type transistors disposed on the same side are connected and flush in the second direction, and the channel regions of the N-type transistors are spaced apart from each other and at least one side is flush in the second direction.

In some embodiments, the N-type transistor and the P-type transistor each have a gate layer and a source-drain metal layer that are rectangular in a top view;
and the gate layer and the source-drain metal layer are connected with each other, a length direction of the gate layer extends along the first direction, and a length direction of the source-drain metal layer extends along the second direction;
wherein an overlapping region of the gate layer and the source-drain metal layer is the channel region.

In some embodiments, each of the logic circuits is further connected to a first DC power supply line and a second DC power supply line respectively and is configured to perform logic processing based on a signal provided by the first DC power supply line and a signal provided by the second DC power supply line;
wherein a width of at least one of the first DC power supply line and the second DC power supply line in the second direction is greater than or equal to a width threshold.

In some embodiments, the first DC power supply line and the second DC power supply line are respectively disposed on two sides of the plurality of logic circuit groups in the second direction and both extend along the first direction, and the width of the first DC power supply line in the second direction is equal to the width of the second DC power supply line in the second direction.

In some embodiments, the decoder circuit is disposed on one side of a substrate, in the decoder circuit, interconnected parts are connected through a plurality of layers of metal wires stacked sequentially in a direction away from the substrate, each two adjacent layers of metal wires are connected with each other through a via hole, and overlapping areas are all less than an area threshold.

In some embodiments, in the decoder circuit, the interconnected parts are connected by a total of three layers of metal wires, namely a first metal wire, a second metal wire, and a third metal wire, which are sequentially stacked in the direction away from the substrate;
wherein the first metal wire includes a plurality of line segments extending along the first direction and a plurality of line segments extending along the second direction, the second metal wire includes a plurality of line segments extending along the second direction, and the third metal wire includes a plurality of line segments extending along the first direction;
and the first DC power supply line and the second DC power supply line connected to each of the logic circuits are both disposed in the same layer as the third metal wire.

In some embodiments, the decoder circuit is a 3-to-8 decoder circuit; and the plurality of logic circuit groups are classified into a first logic circuit group and eight second logic circuit groups arranged sequentially along the first direction;
a plurality of logic circuits in the first logic circuit group include: three first NOT gates and a two-input NAND gate arranged sequentially along the second direction; and
a plurality of logic circuits in the each of the second logic circuit groups include: a three-input NAND gate, a NOR gate, and a second NOT gate arranged sequentially along the second direction;
wherein the first NOT gate and the second NOT gate each include an N-type transistor and a P-type transistor, the two-input NAND gate and the NOR gate each include two N-type transistors and two P-type transistors, and the three-input NAND gate includes three N-type transistors and three P-type transistors; and
input terminals and output terminals of the three first NOT gates are respectively connected to input terminals of the three-input NAND gates in the eight second logic circuit groups, an output terminal of the two-input NAND gate is connected to one input terminal of the NOR gate in each of the second logic circuit groups, and in each of the second logic circuit groups, an output terminal of the three-input NAND gate is connected to another input terminal of the NOR gate, and an output terminal of the NOR gate is connected to an input terminal of the second NOT gate.

In another aspect, a display device is provided, including: a panel driving circuit and a display panel, the panel driving circuit being connected to the display panel and being configured to drive the display panel to display; wherein the panel driving circuit includes the decoder circuit as described in the above aspect.

### BRIEF DESCRIPTION OF DRAWINGS

For clearer descriptions of the technical solutions in the embodiments of the present disclosure, the accompanying drawings required for describing the embodiments are briefly introduced below. Apparently, the accompanying drawings in the following description show merely some embodiments of the present disclosure, and those of ordinary skill in the art may still derive other accompanying drawings from these accompanying drawings without creative efforts.

FIG. 1 is a schematic structural diagram of a decoder circuit according to some embodiments of the present disclosure;

FIG. 2 is a schematic structural diagram of a plurality of logic circuit groups in the decoder circuit according to some embodiments of the present disclosure;

FIG. 3 is a schematic structural diagram of a plurality of logic circuits in one logic circuit group according to some embodiments of the present disclosure;

FIG. 4 is a schematic structural diagram of another decoder circuit according to some embodiments of the present disclosure;

FIG. 5 is a schematic diagram of a circuit structure of a 3-to-8 decoder circuit according to some embodiments of the present disclosure;

FIG. 6 is a schematic diagram of a circuit structure of a NOT gate in the 3-to-8 decoder circuit according to some embodiments of the present disclosure;

FIG. 7 is a schematic diagram of a circuit structure of a two-input NAND gate in the 3-to-8 decoder circuit according to some embodiments of the present disclosure;

FIG. 8 is a schematic diagram of a circuit structure of a NOR gate in the 3-to-8 decoder circuit according to some embodiments of the present disclosure;

FIG. 9 is a schematic diagram of a circuit structure of a three-input NAND gate in the 3-to-8 decoder circuit according to some embodiments of the present disclosure;

FIG. 10 is a schematic diagram of a circuit structure of a logic circuit group in the 3-to-8 decoder circuit according to some embodiments of the present disclosure;

FIG. 11 is a structural layout of a logic circuit group in the 3-to-8 decoder circuit according to some embodiments of the present disclosure;

FIG. 12 is a structural layout of a logic circuit group in another 3-to-8 decoder circuit according to some embodiments of the present disclosure;

FIG. 13 is a structural layout of two adjacent logic circuit groups in a 3-to-8 decoder circuit according to some embodiments of the present disclosure;

FIG. 14 is a structural layout of two adjacent logic circuit groups in another 3-to-8 decoder circuit according to some embodiments of the present disclosure;

FIG. 15 is a structural layout of two adjacent logic circuit groups in yet another 3-to-8 decoder circuit according to some embodiments of the present disclosure;

FIG. 16 is a structural layout of a logic circuit group in yet another 3-to-8 decoder circuit according to some embodiments of the present disclosure;

FIG. 17 is a schematic cross-sectional view of a circuit based on the structure shown in FIG. 16;

FIG. 18 is a structural layout of a 3-to-8 decoder circuit shown based on the structure shown in FIG. 5;

FIG. 19 is a structural layout of a wiring layout in a 3-to-8 decoder circuit shown based on the structure shown in FIG. 18; and

FIG. 20 is a schematic structural diagram of a display device according to some embodiments of the present disclosure.

### DETAILED DESCRIPTION

For clearer descriptions of the objects, technical solutions, and advantages of the present disclosure, the embodiments of the present disclosure are further described in detail below with reference to the accompanying drawings.

FIG. 1 is a schematic structural diagram of a decoder circuit according to some embodiments of the present disclosure. As shown in FIG. 1, the decoder circuit includes: a plurality of logic circuit groups 01 arranged sequentially along a first direction X1 and interconnected.

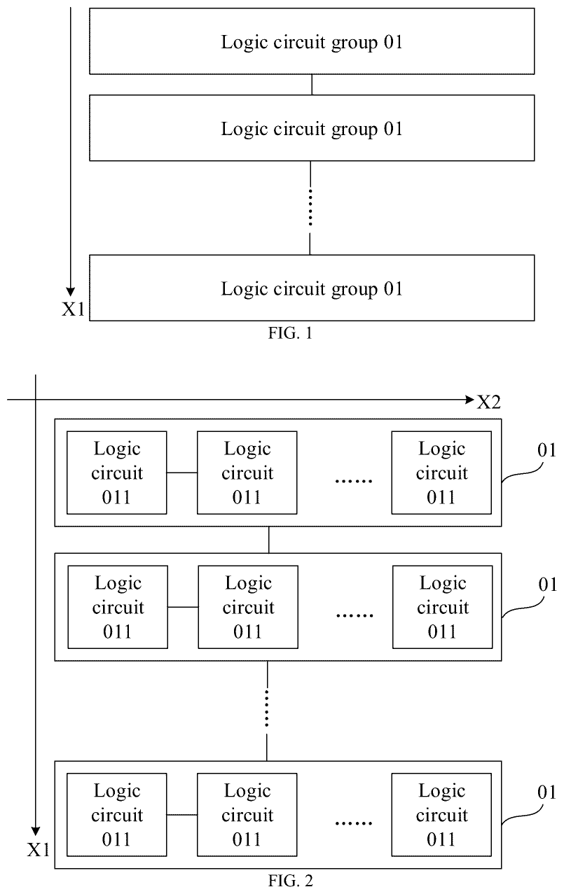

Referring to FIG. 2 based on FIG. 1, it may be seen that each logic circuit group 01 includes: a plurality of logic circuits 011 arranged sequentially along a second direction X2 and interconnected. The second direction X2 is intersected with the first direction X1. For example, the second direction X2 and the first direction X1 may be perpendicular to each other, that is, at an angle of 90 degrees.

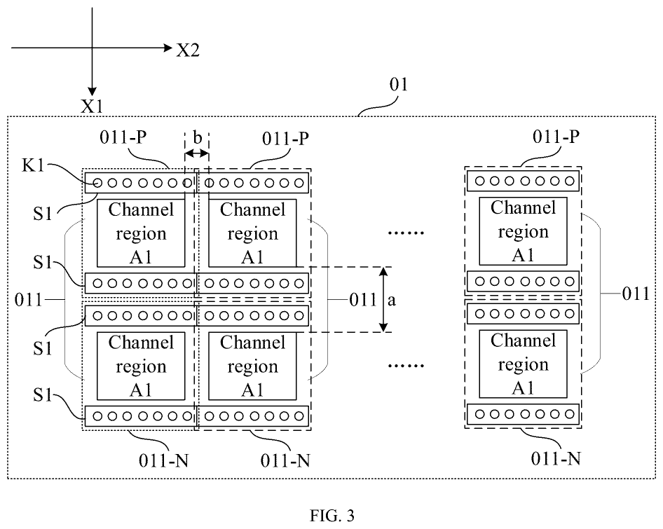

Referring to FIG. 3 based on FIG. 2, it may be seen that each logic circuit 011 includes: at least one N-type transistor 011-N and at least one P-type transistor 011-P interconnected. For example, in FIG. 3, each logic circuit 011 includes one N-type transistor 011-N and one P-type transistor 011-P. Moreover, FIG. 3 merely schematically shows a plurality of logic circuits 011 in one logic circuit group 01.

The N-type transistor 011-N and the P-type transistor 011-P each may have a channel region A1 and substrate isolation regions S1. The substrate isolation regions S1 may be disposed on two sides of the channel region A1 in the first direction X1, and the substrate isolation region S1 is provided with a plurality of vias K1 arranged sequentially along the second direction X2 for interconnection between parts to be connected.

Moreover, in each logic circuit group 01, the N-type transistors in the plurality of logic circuits 011 may be arranged sequentially along the second direction X2, the P-type transistors may be arranged sequentially along the second direction X2, and the P-type transistors and the N-type transistors may be arranged sequentially along the first direction X1. Moreover, it may be further seen from FIG. 3 that a distance a between the channel regions of the P-type transistor and the N-type transistor that are adjacent in the first direction X1 is greater than a distance b between channel regions of two adjacent transistors of the same type in the second direction X2, and the transistors of the same type include P-type transistors and N-type transistors, (that is, a>b).

In this way, the P-type transistor and the N-type transistor can be effectively separated by the substrate isolation region S1 with the vias K1, which ensures that a sufficiently large distance can be maintained between the P-type transistor and the N-type transistor and can reduce resistance of switching and contact in the substrate isolation region S1, so that the decoder circuit has better stability, thereby preventing occurrence of a latch up effect. In addition, it may be further seen from FIG. 3 that this layout manner can also make rational use of space.

In some embodiments, the P-type transistors described in the embodiments of the present disclosure may all be PMOS transistors, and the N-type transistors described in the embodiments of the present disclosure may all be NMOS transistors.

In summary, some embodiments of the present disclosure provide a decoder circuit. The decoder circuit includes a plurality of logic circuit groups arranged along a first direction, each logic circuit group includes a plurality of logic circuits arranged along a second direction intersected with the first direction, and each logic circuit includes N-type transistors and P-type transistors. Moreover, in each logic circuit group, the N-type transistors and the P-type transistors are both arranged along a second direction, the N-type transistors and the P-type transistors are arranged along a first direction, substrate isolation regions of any transistor are disposed on two sides of the transistor in the first direction, and the substrate isolation region is provided with vias arranged along the second direction. In this way, the P-type transistor and the N-type transistor can be separated by the substrate isolation region with vias, so that a distance between the P-type transistor and the N-type transistor adjacent to each other is greater than a distance between two adjacent transistors of the same type (e.g., N-type transistors or P-type transistors), thereby ensuring that a sufficiently large distance is maintained between the N-type transistor and the P-type transistor. Therefore, mutual interference between different types of transistors can be prevented, so that the circuit has good stability, thereby preventing occurrence of a latch up effect.

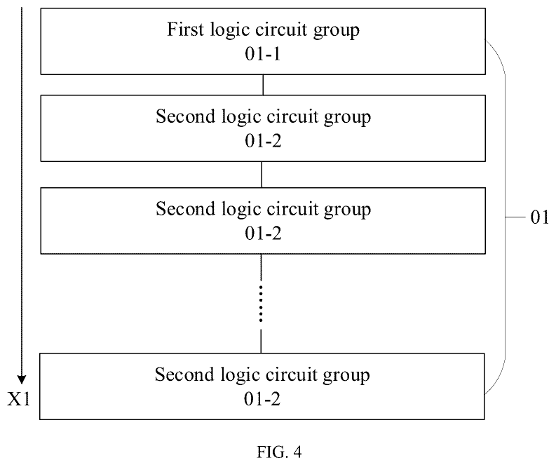

In some embodiments, the decoder circuit according to the embodiments of the present disclosure may be a 3-to-8 decoder circuit or a 3-to-8 decoder. The 3-to-8 decoder is a circuit that decodes an inputted 3-bit binary number into an 8-bit decimal output. Correspondingly, it may be seen from the decoder circuit shown in FIG. 4 that the plurality of logic circuit groups 01 described in the embodiments of the present disclosure may be classified into a first logic circuit group 01-1 and eight second logic circuit groups 01-2 arranged sequentially along the first direction X1.

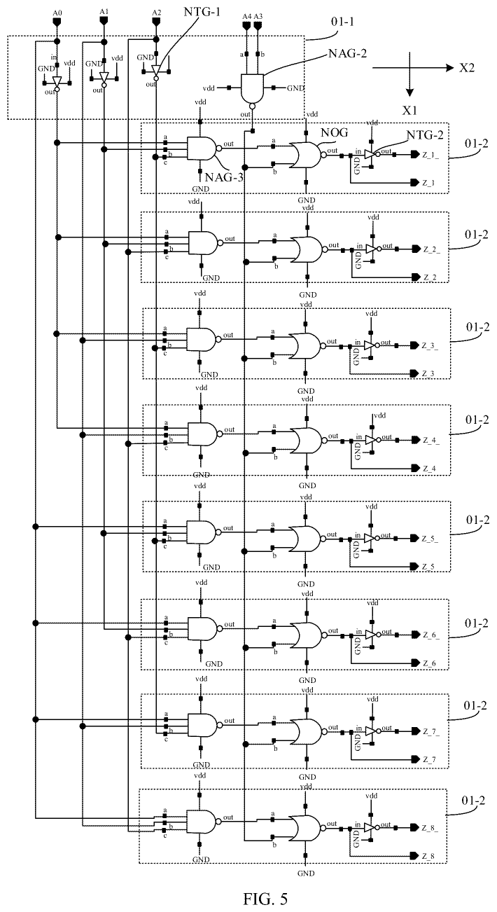

Based on the structure shown in FIG. 4, FIG. 5 is a diagram of a circuit structure of a 3-to-8 decoder. It may be seen from FIG. 5 that a plurality of logic circuits 011 in the first logic circuit group 01-1 may include: three first NOT gates (NTG-1) and a two-input NAND gate (NAG-2) arranged sequentially along the second direction X2. That is, the first logic circuit group 01-1 may include four logic circuits 011. A plurality of logic circuits 011 in each second logic circuit group 01-2 may include: a three-input NAND gate (NAG-3), a NOR gate (NOG), and a second NOT gate (NTG-2) arranged sequentially along the second direction X2. That is, each second logic circuit group 01-2 may include three logic circuits 011. The NTG may also be referred to as an inverter.

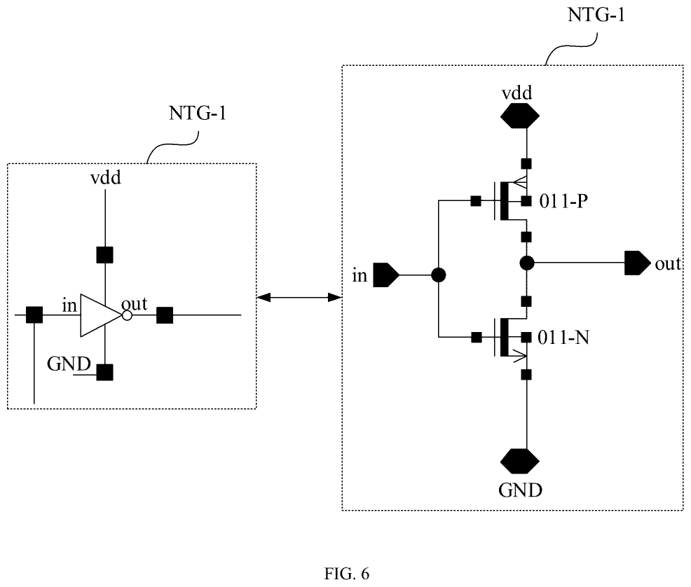

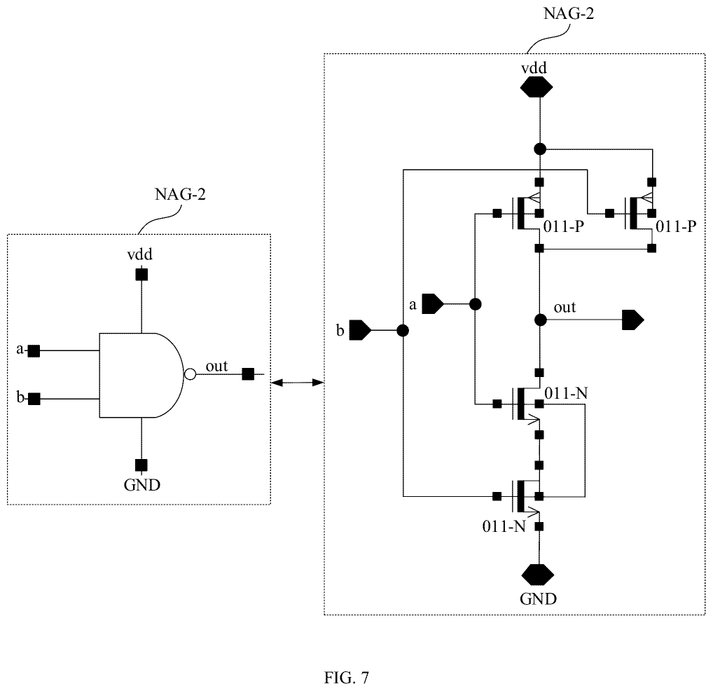

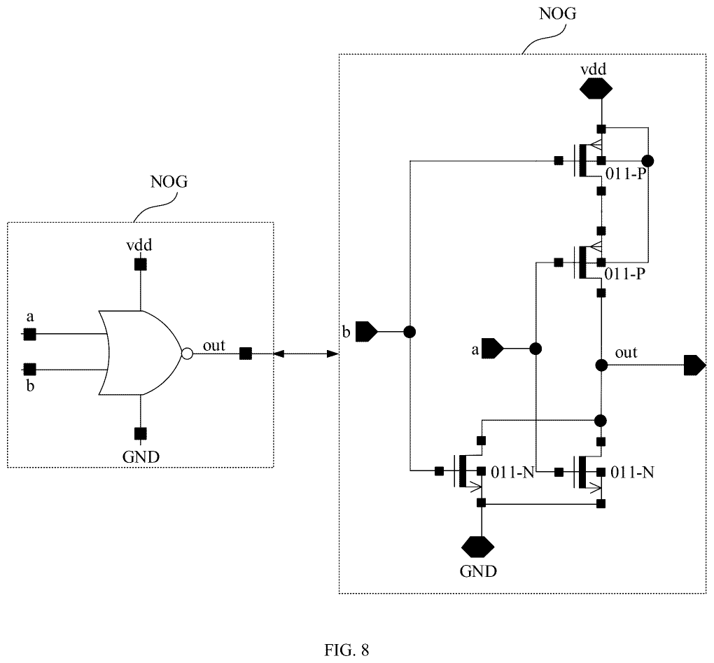

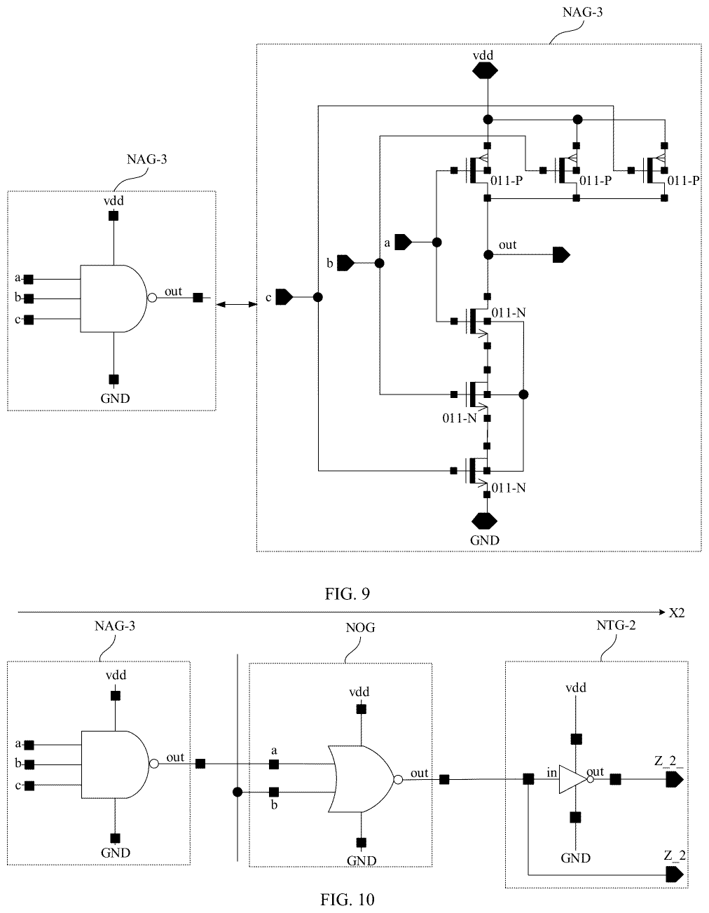

Based on the structure shown in FIG. 5, FIG. 6 is a diagram of an equivalent circuit of the NTG-1 (the same applies to the NTG-2). FIG. 7 is a diagram of an equivalent circuit of the NAG-2. FIG. 8 is a diagram of an equivalent circuit of the NOG. FIG. 9 is a diagram of an equivalent circuit of the NAG-3.

It may be seen from FIG. 6 that the NTG-1 and the NTG-2 may each include an N-type transistor 011-N and a P-type transistor 011-P. Moreover, a gate of the P-type transistor 011-P and agate of the N-type transistor 011-N may both be connected to an input terminal in, a first electrode of the P-type transistor 011-P may be connected to a power supply terminal vdd, a second electrode of the P-type transistor 011-P and the second electrode of the N-type transistor 011-N may both be connected to an output terminal out, and a first electrode of N-type transistor 011-N is connected to a ground terminal GND, that is, grounded.

It may be seen from FIG. 7 and FIG. 8 that the NAG-2 and the NOG may each include two N-type transistors 011-N and two P-type transistors 011-P. Moreover, in the NAG-2, gates of the two P-type transistors 011-P and gates of the two N-type transistors 011-N may be connected to two input terminals a and b respectively, first electrodes of the two P-type transistors 011-P may be connected to the power supply terminal vdd, second electrodes of the two P-type transistors 011-P and a second electrode of one N-type transistor 011-N may be connected to the output terminal out, a first electrode of the N-type transistor 011-N may be connected to a second electrode of the other N-type transistor 011-N, and a first electrode of the other N-type transistor 011-N may be grounded. In the NOG, gates of the two P-type transistors 011-P and gates of the two N-type transistors 011-N may be connected to the two input terminals a and b respectively, a first electrode of one P-type transistor 011-P may be connected to the power supply terminal vdd, a second electrode of the P-type transistor 011-P may be connected to a first electrode of the other P-type transistor 011-P, a second electrode of the other P-type transistor 011-P and second electrodes of the two N-type transistors 011-N may both be connected to the output terminal out, and first electrodes of the two N-type transistors 011-N may both be grounded.

It may be seen from FIG. 9 that the NAG-3 may include three N-type transistors 011-N and three P-type transistors 011-P. Moreover, gates of the three N-type transistors 011-N and gates of the three P-type transistors 011-P may all be connected to three input terminals a, b, and c respectively, first electrodes of the three P-type transistors 011-P may all be connected to the power supply terminal vdd, second electrodes of the three P-type transistors 011-P and a second electrode of one N-type transistor 011-N may all be connected to the output terminal out, a first electrode of the N-type transistor 011-N may be connected to a second electrode of another N-type transistor 011-N, a first electrode of the another N-type transistor 011-N may be connected to a second electrode of yet another N-type transistor 011-N, and a first electrode of the yet another N-type transistor 011-N may be grounded.

Moreover, input terminals (identified as in, a, b, and/or c) and output terminals out of the three NTG-1 may be respectively connected to input terminals of the NAG-3 in the eight second logic circuit groups 01-2, an output terminal of the NAG-2 may be connected to one input terminal of the NOG in each second logic circuit group 01-2, and in each second logic circuit group 01-2, an output terminal of the NAG-3 is connected to another input terminal of the NOG, and an output terminal of the NOG is connected to an input terminal of the NTG-2.

FIG. 5 further schematically shows three input terminals A0, A1, and A2 respectively connected to the three NTG-1, two input terminals A3 and A4 of the NAG-2, and output terminals Z_n_ and Z_n of respective NTG-2, where n refers to an n^{th} second logic circuit group 01-2 and n is less than or equal to 8. For example, for a 2^{nd} second logic circuit group 01-2 shown in FIG. 5, output terminals of the NTG-2 thereof are respectively identified as Z_2_ and Z_2. An output of the 3-to-8 decoder may be obtained from signals inputted by A0, A1, and A2, and signals inputted by A3 and A4 are to enable the 3-to-8 decoder to have a selection function. When the signals inputted by A3 and A4 are both at an active level, output timing of the 3-to-8 decoder can be active.

Based on the structures shown in FIG. 5 to FIG. 9, FIG. 10 is a diagram of a circuit structure of the 2^{nd} second logic circuit group 01-2 arranged from top to bottom along the first direction X1. It may be further seen from FIG. 10 that the second logic circuit group 01-2 includes NAG-3+NOG+NTG-2 connected in sequence along the second direction X2.

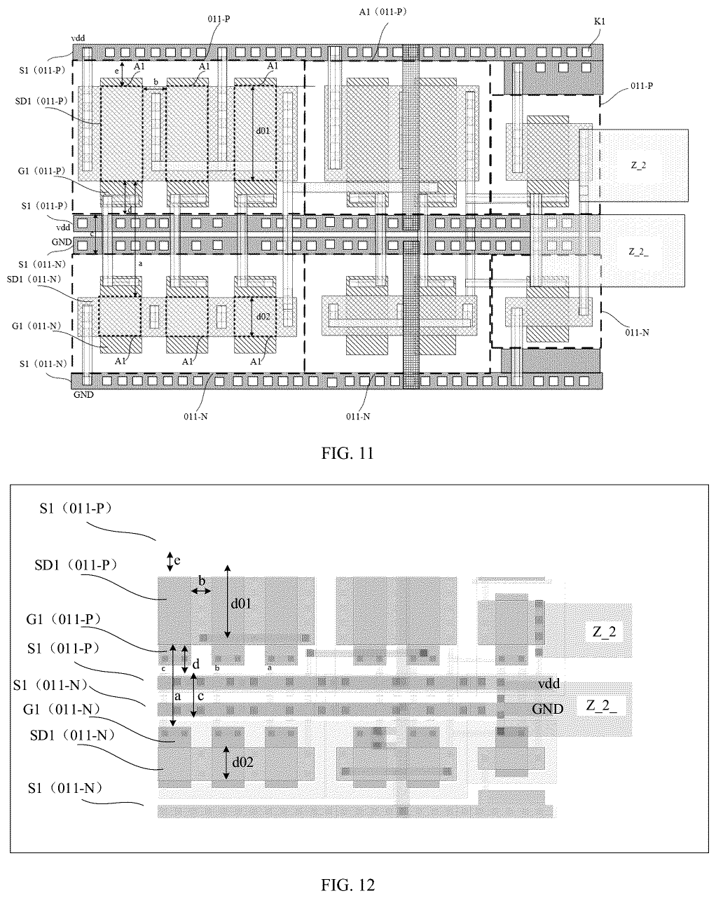

Based on the structure shown in FIG. 10, FIG. 11 and FIG. 12 are respectively structural layouts of the 2^{nd} second logic circuit group 01-2. FIG. 11 and FIG. 12 are different in different drawing manners. It may be seen from FIG. 11 and FIG. 12 that the N-type transistor 011-N and the P-type transistor 011-P may each have a gate layer G1 and a source-drain metal layer SD1 that are rectangular in a top view. Moreover, the gate layer G1 and the source-drain metal layer SD1 may are connected with each other, a length direction of the gate layer G1 may extend along the first direction X1, and a length direction of the source-drain metal layer SD1 may extend along the second direction X2. That is, the length directions of the gate layer G1 and the source-drain metal layer SD1 are intersected. In this way, the purpose of making rational use of space can be further achieved. An overlapping region of the gate layer G1 and the source-drain metal layer SD1 is the channel region A1. FIG. 11 further schematically identifies the channel region A1.

In some embodiments, still referring to FIG. 11 and FIG. 12, it may be seen that in two adjacent substrate isolation regions S1 in the P-type transistor and the N-type transistor that are adjacent in the first direction X1, a distance c between an edge of one substrate isolation region S1 (e.g., the substrate isolation region S1 disposed below the channel region A1 in the P-type transistor) away from the other substrate isolation region S1 (e.g., the substrate isolation region S1 disposed above the channel region A1 in the N-type transistor) and an edge of the other substrate isolation region S1 away from the one substrate isolation region S1 is greater than the distance b between the channel regions A1 of two adjacent transistors of the same type in the second direction, (that is, c>b). In this way, it can be further ensured that a sufficiently large distance is maintained between the P-type transistor and the N-type transistor.

In some embodiments, still referring to FIG. 11 and FIG. 12, it may be further seen that for each transistor in the P-type transistor and the N-type transistor that are adjacent in the first direction X1, in the substrate isolation regions in the transistor, a distance between the substrate isolation region S1 close to the other adjacent transistor and the channel region A1 of the transistor is greater than a distance between the substrate isolation region S1 away from the other adjacent transistor and the channel region A1 of the transistor.

In both FIG. 11 and FIG. 12, the P-type transistor is taken as an example. Referring to FIG. 11 and FIG. 12, it may be seen that in the substrate isolation regions in the P-type transistor, a distance d between the substrate isolation region S1 close to an adjacent N-type transistor (i.e., the substrate isolation region S1 disposed below the channel region A1) and the channel region A1 of the transistor is greater than a distance e between the substrate isolation region S1 away from another adjacent transistor (i.e., the substrate isolation region S1 disposed above the channel region A1) and the channel region A1 of the transistor, (that is, d>e). In this way, it can also be further ensured that a sufficiently large distance is maintained between the P-type transistor and the N-type transistor.

In some embodiments, referring to FIG. 11 and FIG. 12, it may be seen that the distance a between the channel regions of the P-type transistor and the N-type transistor that are adjacent in the first direction X1 may also be greater than a difference between a width d01 of the channel region of the P-type transistor and a width d02 of the channel region of the N-type transistor, that is, a>d01-d02. Moreover, the width d01 of the channel region of the P-type transistor may also be greater than the width d02 of the channel region of the N-type transistor. A direction of both the widths may be parallel to the first direction, which may be a width of a long side of the channel region. In this way, it can also be further ensured that a sufficiently large distance is maintained between the P-type transistor and the N-type transistor.

In some embodiments, referring to FIG. 11 and FIG. 12, it may be seen that, in the embodiments of the present disclosure, an area of the substrate isolation region S1 of the P-type transistor may be greater than an area of the substrate isolation region S1 of the N-type transistor. In addition, for the structure shown in FIG. 11, an area of the uppermost substrate isolation region S1 (i.e., the substrate isolation region S1 above the channel region A1 of the P-type transistor) may generally be maximum.

In some embodiments, still referring to FIG. 11 and FIG. 12, it may be seen that in each logic circuit 011, the substrate isolation regions S1 of the P-type transistors 011-P disposed on the same side may be adjacent and flush in the second direction X2, and the channel regions A1 of the P-type transistors 011-P may be spaced apart from each other and at least one side may be flush in the second direction X2. Moreover, the substrate isolation regions A1 of the N-type transistors 011-N disposed on the same side are connected and flush in the second direction X2, and the channel regions A1 of the N-type transistors 011-N may be spaced apart from each other and at least one side is flush in the second direction X2. That is, the substrate isolation regions S1 of the transistors disposed in the same row may be an entirety, and a row direction is parallel to the second direction X2. In this way, purposes of rational use of space and reasonable layout can be achieved.

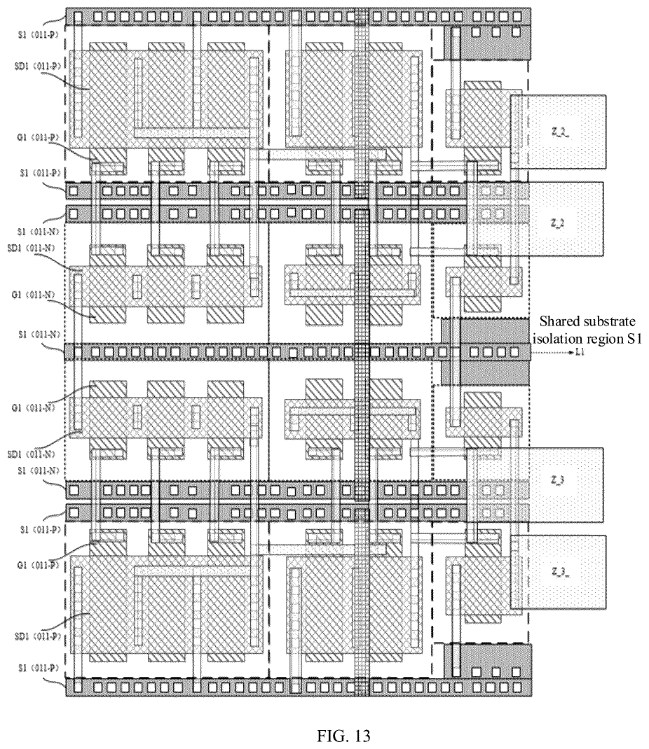

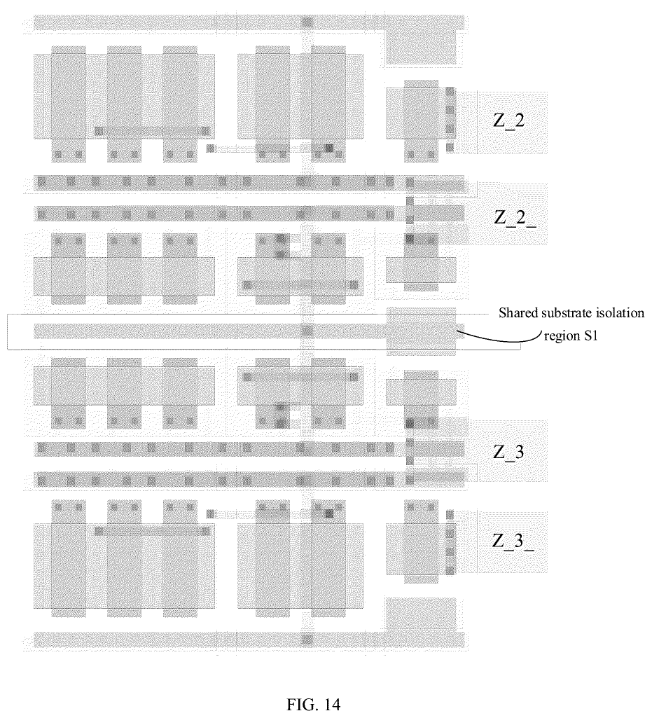

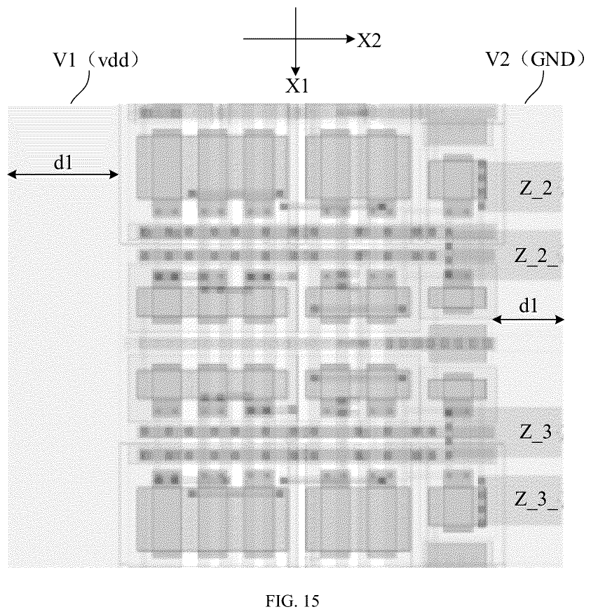

Based on the structures shown in FIG. 11 and FIG. 12, FIG. 13 and FIG. 14 are respectively structural layouts of a 2^{nd} second logic circuit group 01-2 and a 3^{rd} second logic circuit group 01-2 adjacent thereto. Referring to FIG. 13 and FIG. 14, it may be seen that each two adjacent logic circuit groups 01 described in the embodiments of the present disclosure may be arranged in mirror symmetry along an axis L1 extending in the second direction X2. Correspondingly, the transistors disposed on two sides of the axis L1 may be of the same type. That is, for each two adjacent logic circuit groups 01, two adjacent rows of transistors thereof may all be N-type transistors or P-type transistors.

For example, the structures shown in FIG. 13 and FIG. 14 are both described based on an example in which the transistors disposed on the two sides of the axis L1 are N-type transistors. That is, in the 2^{nd} second logic circuit group 01-2 and the 3^{rd} second logic circuit group 01-2 adjacent thereto, one row of P-type transistors, one row of N-type transistors, one row of N-type transistors, and one row of P-type transistors may be sequentially arranged along the first direction X1.

Based on this, still referring to FIG. 13 and FIG. 14, it may be further seen that in the embodiments of the present disclosure, in each two adjacent logic circuit groups 01, the transistors disposed on the two sides of the axis L1 may share the same substrate isolation region S1. In this way, the structure can be simplified, costs can be saved, and the layout can be further facilitated. For example, for the structures shown in FIG. 13 and FIG. 14, in the 2^{nd} second logic circuit group 01-2 and the 3^{rd} second logic circuit group 01-2 adjacent thereto, two adjacent rows of N-type transistors share the same substrate isolation region S1.

In some embodiments, referring to FIG. 5 to FIG. 9, it may be further seen that each logic circuit 011 described in the embodiments of the present disclosure may further be connected to a first DC power supply line V1 and a second DC power supply line V2 respectively and may be configured to perform logic processing based on a signal provided by the first DC power supply line V1 and a signal provided by the second DC power supply line V2. For example, the first DC power supply line V1 may be a charging power line vdd that provides a high-potential signal as shown in the figure. The second DC power supply line V2 may be a ground wire GND that provides a low-potential signal.

In some embodiments, referring to the partial structural layout shown in FIG. 15, in the embodiments of the present disclosure, a width d1 of at least one of the first DC power supply line V1 and the second DC power supply line V2 in the second direction X2 may be greater than or equal to a width threshold. For example, the width threshold may be 5 μm. The widths d1 of the first DC power supply line V1 and the second DC power supply line V2 in the second direction X2 may be equal to 5 μm.

That is, the width of the DC power supply line connected to the decoder circuit described in the embodiments of the present disclosure may be greater. In this way, square resistance on a signal line can be reduced, thereby reducing an IR drop and further preventing the occurrence of the latch up effect. The square resistance refers to resistance of a rectangular wire in a current direction. Within a scope allowed by an overall area of the decoder circuit, the greater the width of the DC power supply line, the better.

Still referring to FIG. 15, it may be seen that the first DC power supply line V1 (e.g., vdd) and the second DC power supply line V2 (e.g., GND) may be respectively disposed on two sides of the plurality of logic circuit groups 01 in the second direction X2 and may both extend along the first direction X1, and the width of the first DC power supply line V1 in the second direction X2 and the width of the second DC power supply line V2 in the second direction X2 may be equal. In this way, the purpose of rational use of space can be further achieved, and IR drops on two DC power supply lines providing different potentials are equal.

In addition, referring to FIG. 11, it may be further seen that the substrate isolation regions S1 disposed on two sides of the channel region A1 in the P-type transistor may be connected to the first DC power supply line V1 (e.g., vdd) to receive power signals of the same potential. The substrate isolation regions S1 disposed on two sides of the channel region A1 in the N-type transistor may be connected to the second DC power supply line V2 (e.g., GND) to receive power signals of the same potential.

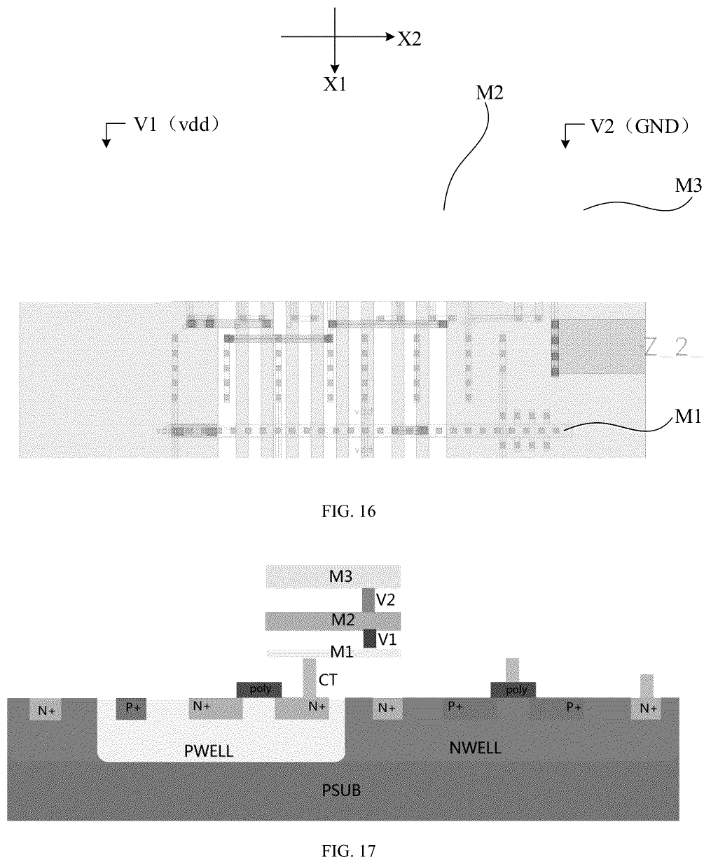

In some embodiments, based on the structure shown in FIG. 15, FIG. 16 is a partial wiring layout. FIG. 17 is a cross-sectional view of wiring. Referring to FIG. 16 and FIG. 17, it may be seen that the decoder circuit described in the embodiments of the present disclosure may be disposed on one side of a substrate (or a base substrate). Moreover, in the decoder circuit, interconnected parts may be connected through a plurality of layers of metal wires stacked sequentially in a direction away from the substrate, each two adjacent layers of metal wires may be connected with each other through a via hole, and overlapping areas of each two adjacent layers of metal wires may be all less than an area threshold. That is, the overlapping area is small, which can reduce generation of parasitic capacitance, and can also achieve purposes of making rational use of space and further increasing a line width.

For example, in the decoder circuit shown in FIG. 16 and FIG. 17, the interconnected parts are connected by a total of three layers of metal wires, namely a first metal wire M1, a second metal wire M2, and a third metal wire M3, which are sequentially stacked in a direction away from the substrate isolation region S1.

Referring to FIG. 16, it may be seen that the first metal wire M1 may include a plurality of line segments extending along the first direction X1 and a plurality of line segments extending along the second direction X2, the second metal wire M2 may include a plurality of line segments extending along the second direction X2, and the third metal wire M3 may include a plurality of line segments extending along the first direction X1. The first DC power supply line V1 (e.g., vdd) and the second DC power supply line V2 (e.g., GND) connected to each logic circuit 011 may be disposed in the same layer as the third metal wire M3. That is, except for the first metal wire M1, the second metal wire M2 may be laid out by horizontal (a length direction extends along the second direction X2) wiring, and the third metal wire M3 may be laid out by horizontal (a length direction extends along the first direction X1) wiring.

It is to be noted that in the cross-sectional view shown in FIG. 17, PWELL refers to a P well, NWELL refers to an N well, N+ refers to a doped N ion, P+ refers to a doped P ion, and PSUB refers to the substrate isolation region. poly refers to an active layer, CT, V1, and V2 all refer to via holes used to overlap different layers. FIG. 17 shows a NMOS.

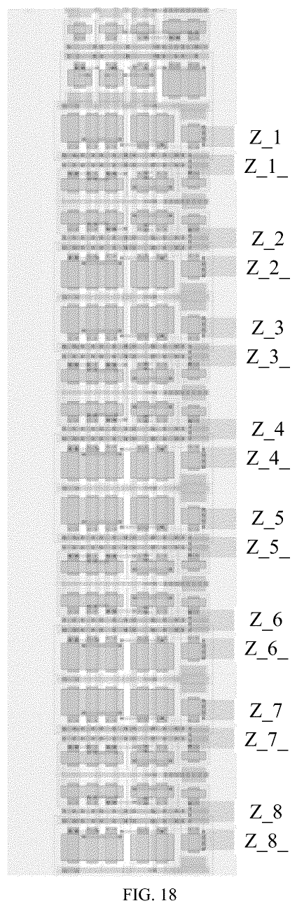

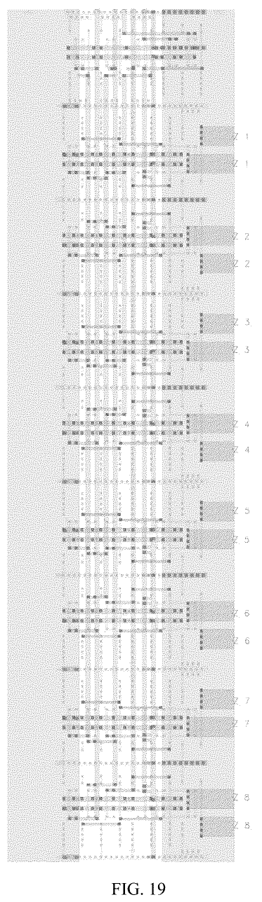

Taking the above drawings as an example, FIG. 18 is an overall structural layout of a 3-to-8 decoder. FIG. 19 is a wiring layout in an overall structural layout of a 3-to-8 decoder. Referring to FIG. 18 and FIG. 19 and the content disclosed in the above embodiments, the layout design provided in the embodiments of the present disclosure may implement a 3-to-8 decoding function, and certainly, in some other embodiments, may implement other decoding functions. Moreover, on the one hand, in the embodiments of the present disclosure, the latch up effect can be reduced by increasing a distance between the NMOS transistor and the PMOS transistor and increasing connections of contact holes in the substrate isolation region. Based on this, each two adjacent logic circuit groups may be arranged by mirroring, so that transistors of the same type in different logic circuit groups can be adjacent, thereby achieving purposes of sharing the substrate isolation region and making rational use of space. On the other hand, in the embodiments of the present disclosure, by increasing the line width of the DC power supply line, the square resistance can be reduced, and an influence of the IR drop can be reduced. Further, in the embodiments of the present disclosure, metal wires may be rationally laid out to reduce an overlapping area and widen the wires, thereby reducing an influence of parasitic capacitance on the operation of the decoder circuit. In the embodiments of the present disclosure, through layout optimization, original design rules are followed, and better beneficial effects are achieved, thereby improving layout reliability.

In summary, some embodiments of the present disclosure provide a decoder circuit. The decoder circuit includes a plurality of logic circuit groups arranged along a first direction, each logic circuit group includes a plurality of logic circuits arranged along a second direction intersected with the first direction, and each logic circuit further includes N-type transistors and P-type transistors. Moreover, in each logic circuit group, the N-type transistors and the P-type transistors are both arranged along a second direction, the N-type transistors and the P-type transistors are arranged along a first direction, substrate isolation regions of any transistor are disposed on two sides of the transistor in the first direction, and the substrate isolation region is provided with vias arranged along the second direction. In this way, the P-type transistor and the N-type transistor can be separated by the substrate isolation region with vias, so that a distance between the P-type transistor and the N-type transistor adjacent to each other is greater than a distance between two adjacent transistors of the same type (e.g., N-type transistors or P-type transistors), thereby ensuring that a sufficiently large distance is maintained between the N-type transistor and the P-type transistor. Therefore, mutual interference between different types of transistors can be prevented, so that the circuit has good stability, thereby preventing occurrence of a latch up effect.

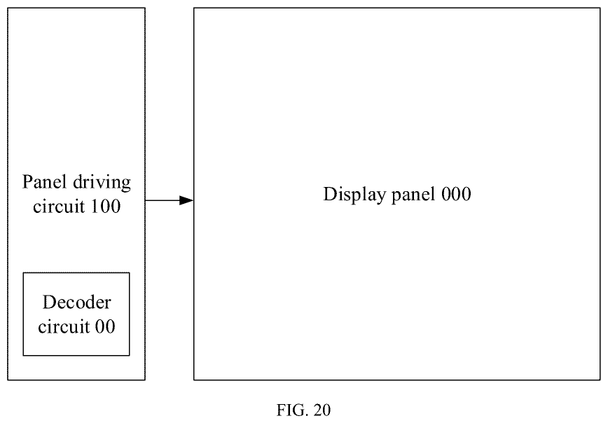

FIG. 20 is a schematic structural diagram of a display device according to some embodiments of the present disclosure. As shown in FIG. 20, the display device includes: a panel driving circuit 100 and a display panel 000. The panel driving circuit 100 is connected to the display panel 000 and is configured to drive the display panel 000 to display. The panel driving circuit 100 may include the decoder circuit as described in the above embodiments.

In some embodiments, the display device described in the embodiments of the present disclosure may be a silicon-based micro display. That is, the decoder circuit described in the embodiments of the present disclosure is applicable to silicon-based products, such as silicon-based organic light-emitting diode (OLED) products. Certainly, in some other embodiments, the display device may alternatively be any product or component having a display function, such as an electronic paper, a mobile phone, a tablet computer, a television, a display, a notebook computer, or a navigator.

It should be understood that the terms used in the embodiments of the present disclosure are only used to explain the embodiments of the present disclosure and are not intended to limit the present disclosure. Unless otherwise defined, the technical terms or scientific terms used in the embodiments of the present disclosure should have the same meanings as commonly understood by those of ordinary skill in the art to which the present disclosure belongs.

For example, “first,” “second,” or “third”, and similar words which are used in the description and claims of the present disclosure are not intended to indicate any sequence, number, or importance, but are only intended to distinguish different components.

Similarly, similar words such as “one” and “a/an” do not mean a quantity limit, but mean at least one.

Similar words such as “comprise” and “include” are intended to specify that an element or an object before “comprise” and “include” covers elements or objects listed after “comprise” and “include” as well as equivalents thereof, but does not exclude other elements or objects.

The terms “up,” “down,” “left” and “right,” and the like are only used to indicate a relative position relationship, and in a case that an absolute position of an object is described as being changed, the relative position relationship may be changed accordingly. Words such as “connect” and “connection” refer to electrical connections.

The term “and/or” indicates that three relationships may exist. For example, A and/or B indicates that there are three cases of A alone, A and B together, and B alone. The character “/” herein generally means that associated objects before and after the character are in an “or” relationship.

The above are only optional embodiments of the present disclosure and are not intended to limit the present disclosure. Any modification, equivalent replacement, improvement, and the like made within the spirit and principles of the present disclosure shall be included in the protection scope of the present disclosure.

1. A decoder circuit, comprising:
a plurality of logic circuit groups arranged sequentially along a first direction and connected in series;
each of the logic circuit groups comprising: a plurality of logic circuits arranged sequentially along a second direction and connected in series, the second direction being intersected with the first direction;
each of the logic circuits comprising: at least one N-type transistor and at least one P-type transistor, wherein each of the at least one N-type transistor and the at least one P-type transistor has a channel region and two substrate isolation regions, the two substrate isolation regions being respectively disposed on two sides of the channel region in the first direction, and each of the substrate isolation regions is provided with a plurality of vias arranged sequentially along the second direction;
wherein in each of the logic circuit groups, N-type transistors in the plurality of logic circuits are arranged sequentially along the second direction, P-type transistors in the plurality of logic circuits are arranged sequentially along the second direction, a set of the P-type transistors and a set of the N-type transistors are arranged sequentially along the first direction, and a distance between a channel region of a P-type transistor and a channel region of a N-type transistor adjacent to the P-type transistor in the first direction is greater than a distance between channel regions of two adjacent transistors in each of the set of the P-type transistors and the set of the N-type transistors.

2. The decoder circuit according to claim 1, wherein each two adjacent logic circuit groups are arranged in mirror symmetry along an axis extending in the second direction.

3. The decoder circuit according to claim 2, wherein in each two adjacent logic circuit groups, transistors disposed on two sides of the axis share one substrate isolation region which is between the two adjacent logic circuit groups.

4. The decoder circuit according to claim 1, wherein in two adjacent substrate isolation regions respectively in a P-type transistor and a N-type transistor which are adjacent in the first direction, a distance between an edge of one substrate isolation region away from the other substrate isolation region and an edge of the other substrate isolation region away from the one substrate isolation region is greater than the distance between the channel regions of two adjacent transistors in each of the set of the P-type transistors and the set of the N-type transistors.

5. The decoder circuit according to claim 1, wherein for each transistor in a P-type transistor and a N-type transistor which are adjacent in the first direction, a distance between a substrate isolation region in the transistor and close to another transistor adjacent to the transistor and a channel region of the transistor is greater than a distance between a substrate isolation region in the transistor and away from the another transistor adjacent to the transistor and the channel region of the transistor.

6. The decoder circuit according to claim 1, wherein the distance between a channel region of a P-type transistor and a channel region of a N-type transistor adjacent to the P-type transistor in the first direction is greater than a difference between a width of the channel region of the P-type transistor and a width of the channel region of the N-type transistor, the width of the channel region of the P-type transistor is greater than the width of the channel region of the N-type transistor, and a direction of both the widths is parallel to the first direction.

7. The decoder circuit according to claim 1, wherein an area of the substrate isolation region of the P-type transistor is greater than an area of the substrate isolation region of the N-type transistor.

8. The decoder circuit according to claim 1, wherein in each of the logic circuits, substrate isolation regions of P-type transistors disposed on the same side of channel regions of the P-type transistors are connected and flush in the second direction, and the channel regions of the P-type transistors are spaced apart from each other and edges of at least one side of the channel regions are flush in the second direction;
and substrate isolation regions of N-type transistors disposed on the same side of channel regions of the N-type transistors are connected and flush in the second direction, and the channel regions of the N-type transistors are spaced apart from each other and edges of at least one side of the channel regions are flush in the second direction.

9. The decoder circuit according to claim 1, wherein each of the at least one N-type transistor and the at least one P-type transistor has a gate layer and a source-drain metal layer which are rectangular in a top view;
and the gate layer and the source-drain metal layer overlap with each other, a length direction of the gate layer extends along the first direction, and a length direction of the source-drain metal layer extends along the second direction;
wherein the channel region overlaps with an overlapping region of the gate layer and the source-drain metal layer.

10. The decoder circuit according to claim 1, wherein each of the logic circuits is further respectively connected to a first DC power supply line and a second DC power supply line and is configured to perform logic processing based on a signal provided by the first DC power supply line and a signal provided by the second DC power supply line.

11. The decoder circuit according to claim 10, wherein the first DC power supply line and the second DC power supply line are respectively disposed on two sides of the plurality of logic circuit groups in the second direction and both extend along the first direction, and the width of the first DC power supply line in the second direction is equal to the width of the second DC power supply line in the second direction.

12. The decoder circuit according to claim 1, wherein the decoder circuit is disposed on one side of a substrate, at least a part of connections in the decoder circuit is realized by a plurality of layers of metal wires stacked sequentially in a direction away from the substrate, each two adjacent layers of metal wires are connected with each other through a via hole.

13. The decoder circuit according to claim 12, wherein at least a part of connections in the decoder circuit is realized by a total of three layers of metal wires comprising a first metal wire, a second metal wire and a third metal wire which are sequentially stacked in the direction away from the substrate;
wherein the first metal wire comprises a plurality of line segments extending along the first direction and a plurality of line segments extending along the second direction, the second metal wire comprises a plurality of line segments extending along the second direction, and the third metal wire comprises a plurality of line segments extending along the first direction; and
both the first DC power supply line and the second DC power supply line connected to each of the logic circuits are disposed in the same layer as the third metal wire.

14. The decoder circuit according to claim 1, wherein the decoder circuit is a 3-to-8 decoder circuit; and the plurality of logic circuit groups are classified into a first logic circuit group and eight second logic circuit groups arranged sequentially along the first direction;
a plurality of logic circuits in the first logic circuit group comprises: three first NOT gates and a two-input NAND gate arranged sequentially along the second direction; and
a plurality of logic circuits in each of the second logic circuit groups comprises: a three-input NAND gate, a NOR gate, and a second NOT gate arranged sequentially along the second direction;
wherein each of the first NOT gate and the second NOT gate comprises an N-type transistor and a P-type transistor, each of the two-input NAND gate and the NOR gate comprises two N-type transistors and two P-type transistors, and the three-input NAND gate comprises three N-type transistors and three P-type transistors; and
output terminals of the three first NOT gates are respectively connected to a first input terminal of the three-input NAND gates in each of the eight second logic circuit groups, input terminals of the three first NOT gates are respectively connected to a second input terminal of the three-input NAND gate in each of the eight second logic circuit groups, an output terminal of the two-input NAND gate is connected to one input terminal of the NOR gate in each of the second logic circuit groups, and in each of the second logic circuit groups, an output terminal of the three-input NAND gate is connected to another input terminal of the NOR gate, and an output terminal of the NOR gate is connected to an input terminal of the second NOT gate.

15. A display device, comprising: a panel driving circuit and a display panel, the panel driving circuit being connected to the display panel and being configured to drive the display panel to display;
wherein the panel driving circuit comprises the decoder circuit according to claim 1.

16. The display device according to claim 15, wherein each two adjacent logic circuit groups are arranged in mirror symmetry along an axis extending in the second direction.

17. The display device according to claim 16, wherein in each two adjacent logic circuit groups, transistors disposed on two sides of the axis share one substrate isolation region which is between the two adjacent logic circuit groups.

18. The display device according to claim 15, wherein in two adjacent substrate isolation regions respectively in a P-type transistor and a N-type transistor which are adjacent in the first direction, a distance between an edge of one substrate isolation region away from the other substrate isolation region and an edge of the other substrate isolation region away from the one substrate isolation region is greater than the distance between the channel regions of two adjacent transistors in each of the set of the P-type transistors and the set of the N-type transistors.

19. The display device according to claim 15, wherein for each transistor in a P-type transistor and a N-type transistor which are adjacent in the first direction, a distance between a substrate isolation region in the transistor and close to another transistor adjacent to the transistor and a channel region of the transistor is greater than a distance between a substrate isolation region in the transistor and away from the another transistor adjacent to the transistor and the channel region of the transistor.

20. The display device according to claim 15, wherein the distance between a channel region of a P-type transistor and a channel region of a N-type transistor adjacent to the P-type transistor in the first direction is greater than a difference between a width of the channel region of the P-type transistor and a width of the channel region of the N-type transistor, the width of the channel region of the P-type transistor is greater than the width of the channel region of the N-type transistor, and a direction of both the widths is parallel to the first direction.
